(19) United States
(12) Patent Application Publication
(10) Pub. No.: US 2011/0318502 A1
(43) Pub. Date: Dec. 29, 2011

(54) METHODS OF DEPOSITING SIO2 FILMS

(75) Inventors: Kathrine Giles, Wotton-Under-Edge (GB); Andrew Price, Ebbw Vale (GB); Stephen Robert Burgess, Ebbw Vale (GB); Daniel Thoms Archard, Port Talbot (GB)

(73) Assignee: SPP PROCESS TECHNOLOGY SYSTEMS UK LIMITED, Gwent (GB)

(21) Appl. No.: 12/972,602

(22) Filed: Dec. 20, 2010

Related U.S. Application Data
(60) Provisional application No. 61/290,022, filed on Dec. 24, 2009.

(51) Int. Cl. C23C 16/40; C23C 16/56; C23C 16/505

(52) U.S. Cl. 427/535; 427/579

(57) ABSTRACT

This invention relates to a method of depositing an inorganic SiO₂ film at temperatures below 250° C. using plasma enhanced chemical vapour deposition (PECVD) in a chamber including supplying tetraethylorthosilicate (TEOS) and O₂, or a source thereof, as precursors, with an O₂/TEOS ratio of between 15:1 and 25:1.

This invention relates to a method of depositing SiO₂ films and in particular to depositing such films below 250° C. using plasma enhanced chemical vapour deposition (PECVD).

Through silicon vias (TSVs), which can for example be etched vias or trenches in silicon, require a dielectric liner prior to metallic layer deposition. It is highly desirable that such films are good conformal films because of their minimum thickness the dielectric properties have to be good enough to avoid current leakage in normal use. There also has to be limited, if any, moisture absorption following the depositions step, particularly as quite commonly the next step will follow a vacuum break. It is also desirable that they can be deposited at low temperatures, preferably below even 200° C. whilst being conformal and non absorbent.

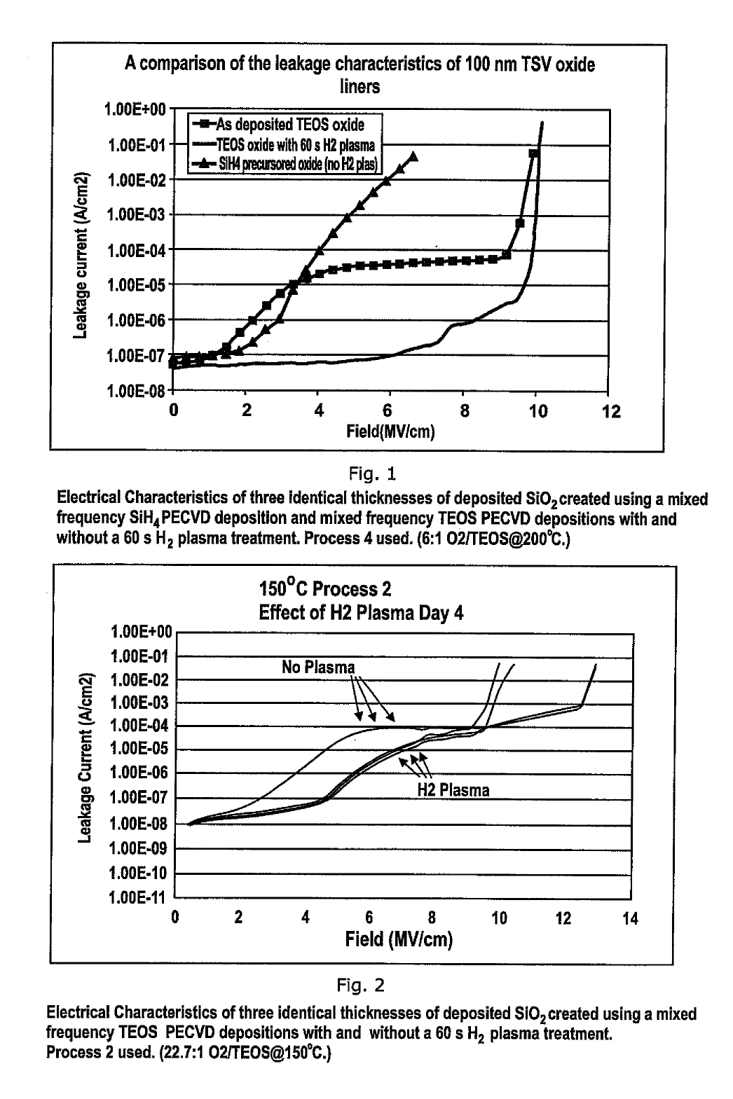

PECVD using TEOS/O₂ precursors have been considered because they have generally good step coverage and the cost of the precursors is relatively low. However, when deposition temperatures are reduced to less than 200° C. to 250° C. the dielectric properties (leakage and ultimate breakdown) become degraded. In an article entitled Characterisation and Preparation SiO₂ and SiOF films using RF PECVD technique from TEOS₂ and TEOS/O₂/CF₄ Precursors by Kim et al—J. Phys. D: Appl. Phs. 37 (2004) 2425-2431—the authors describe films formed from TEOS/O₂ precursors using different ratios of flow rate for the precursors. It will be noted that in FIG. 1a, of that article, the deposition rate at 200° C. falls dramatically and at lower ratios of O₂/TEOS the authors report the incorporation of ethoxy groups into the film. They provide no information about the electrical breakdown characteristics of the films. It will be particularly noted that they report increasing O—H absorption into the film when it is exposed to air after deposition as lower deposition temperatures are used.

From one aspect the invention consists in a method depositing a SiO₂ film that temperatures below 250° C. using plasma enhanced chemical vapour deposition (PECVD) in a chamber including supplying tetraethyl orthosilicate (TEOS) and O₂, or a source thereof, as precursors, with an O₂/TEOS ratio of between 15:1 and 25:1.

Preferably the precursors have deposited using an RF-driven showerhead and it is preferred that the showerhead is driven using a high frequency component and a low frequency component. In that case the high frequency component is preferably 13.56 MH_{z} and the low frequency component is 350 kHz to 2 MHz. The power supplied at the high frequency may be approximately twice the power of the low frequency component.

In any of the above cases, the method may include performing a H₂ plasma treatment on the as deposited film. This treatment may be performed after a vacuum break. It is preferred that the H₂ plasma treatment is sufficient to reform Si—H bonds on the surface of the film.

From another aspect the invention consists in a method of PECVD of a SiO₂ film using a TEOS precursor and an O₂— containing precursor including performing a H₂ plasma treatment on the as deposited film.

The precursors may be deposited through an RF driven showerhead and the showerhead may be driven using a high frequency component and a low frequency component, which may be as described above.

In a still further aspect of the invention may include a method of PEVCD of a SiO₂ film at temperatures below 250° C. using TOS and an O₂— containing precursor deposited through an RF driven showerhead wherein the showerhead is driven using a high frequency component and a low frequency component. These components may be as described above.

In any of the above methods, the film may be deposited at temperatures of the range 150° C. to 200° C.

Although the invention has been defined above it includes any inventive combination of the features set above or in the following description.

The invention may be performed in various ways and specific embodiments will now be described, by way of example, with reference to the accompanying drawings in which:

FIG. 1 shows electrical characteristics of three identical thicknesses of deposited SiO₂ created using a mixed frequency SiH₄ PECVD deposition and mixed frequency TEOS PECVD depositions with and without a 60 s H₂ plasma treatment. Process 4 used. (6:1 O₂/TEOS @ 200 C.);

FIG. 2 shows electrical characteristics of three identical thicknesses of deposited SiO₂, created using a mixed frequency TEOS PECVD depositions with and without a 60 s H₂ plasma treatment. Process 2 used. (22.7:1 O2/TEOS @ 150 C.);

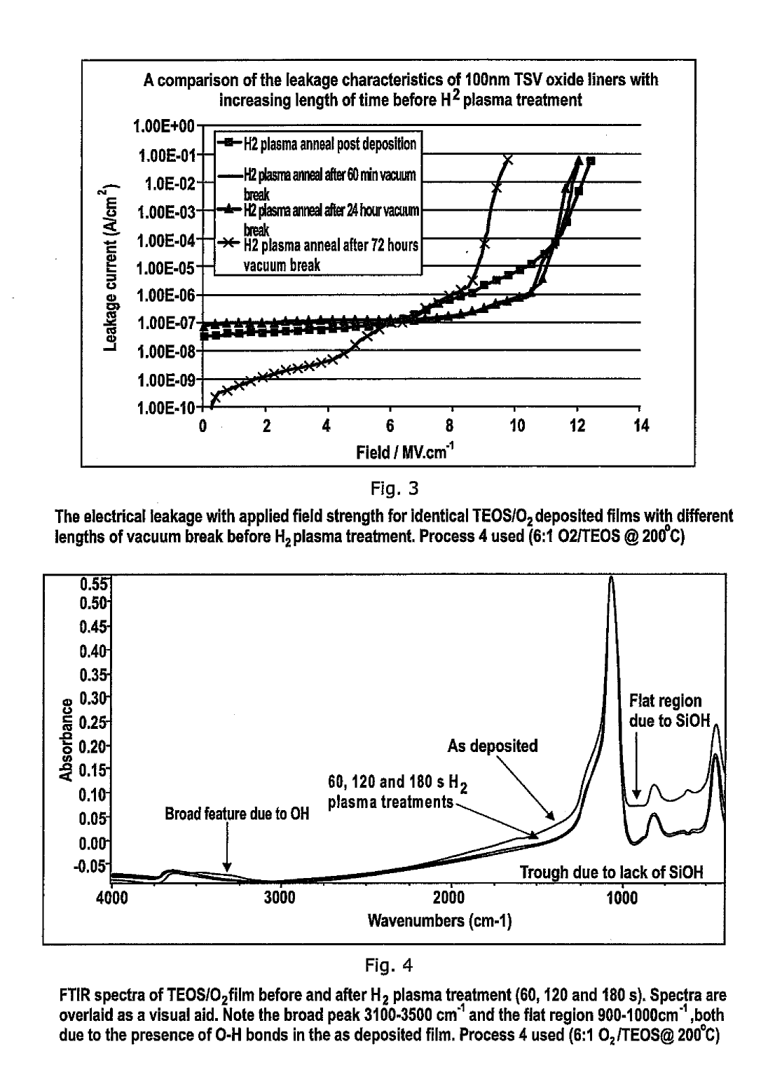

FIG. 3 shows the electrical leakage with applied field strength for identical TEOS/O₂ deposited films with different lengths of vacuum break before H₂ plasma treatment. Process 4 used (6:1 O2/TEOS @200 C);

FIG. 4 shows FTIR spectra of TEOS/O₂ film before and after H2 plasma treatment (60, 120 and 180 sec). Spectra are overlaid as a visual aid. Note the broad peak 3100-3500 cm⁻¹ and the flat region 900-1000 cm⁻¹, both due to the presence of O—H bonds in the as deposited film. Process 4 used (6:1 O2/TEOS @ 200 C);

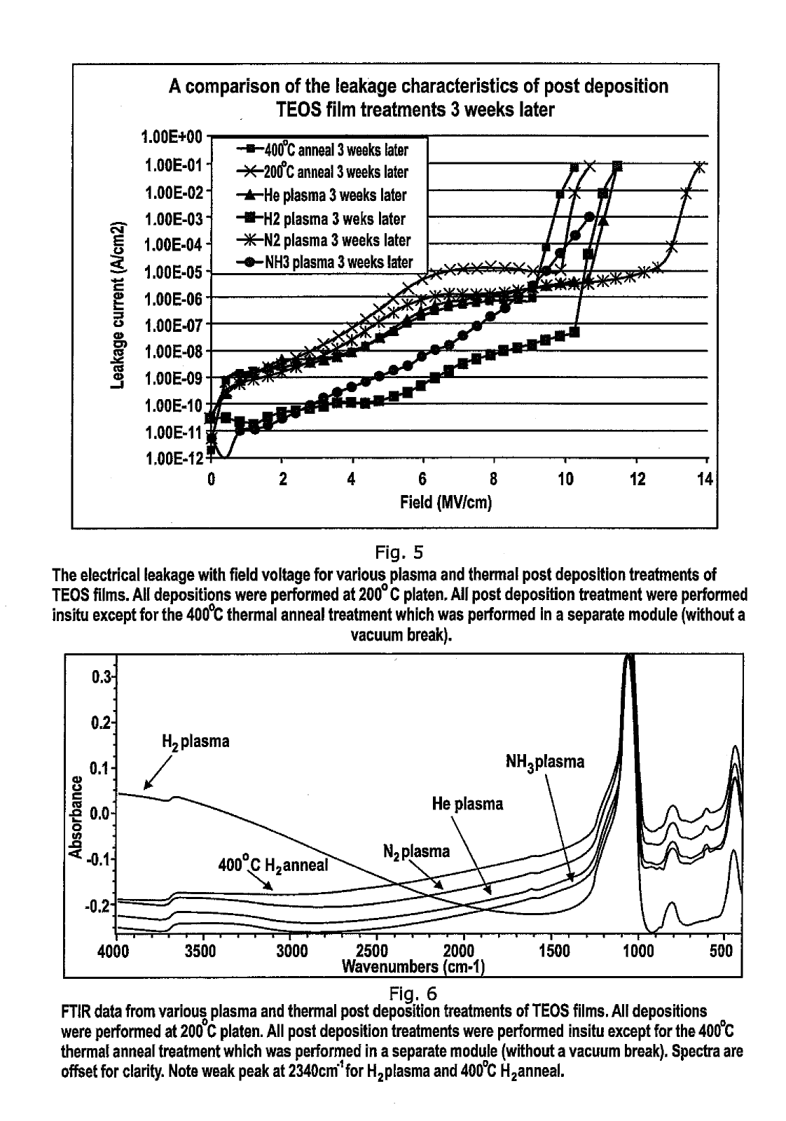

FIG. 5 shows the electrical leakage with field voltage for various plasma and thermal post deposition treatments of TEOS films. All depositions were performed at 200° C. platen. All post deposition treatments were performed insitu except for the 400° C. thermal anneal treatment which was performed in a separate module (without a vacuum break);

FIG. 6 shows FTIR data from various plasma and thermal post deposition treatments of TEOS films. All depositions were performed at 200° C. platen. All post deposition treatments were performed insitu except for the 400° C. thermal anneal treatment which was performed in a separate module (without a vacuum break). Spectra are offset for clarity. Note weak peak at 2340 cm-1 for H₂ plasma and 400° C. H₂ anneal;

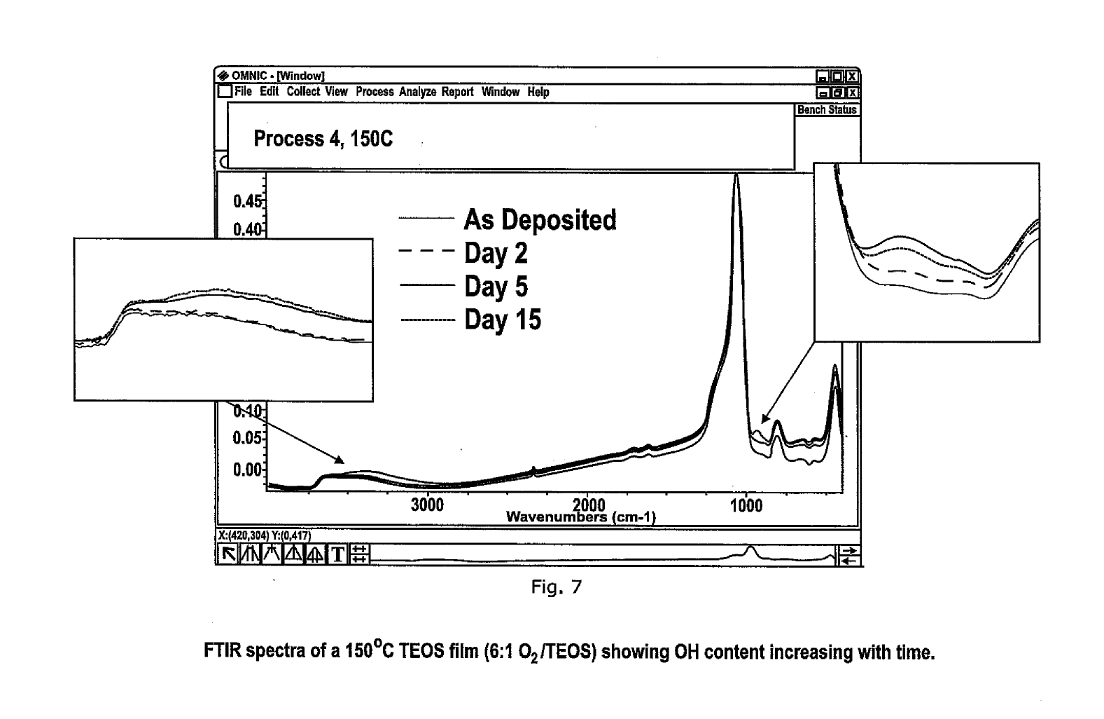

FIG. 7 shows FTIR spectra of a 150° C. TEOS film (6:1 O₂/TEOS) showing OH content increasing with time;

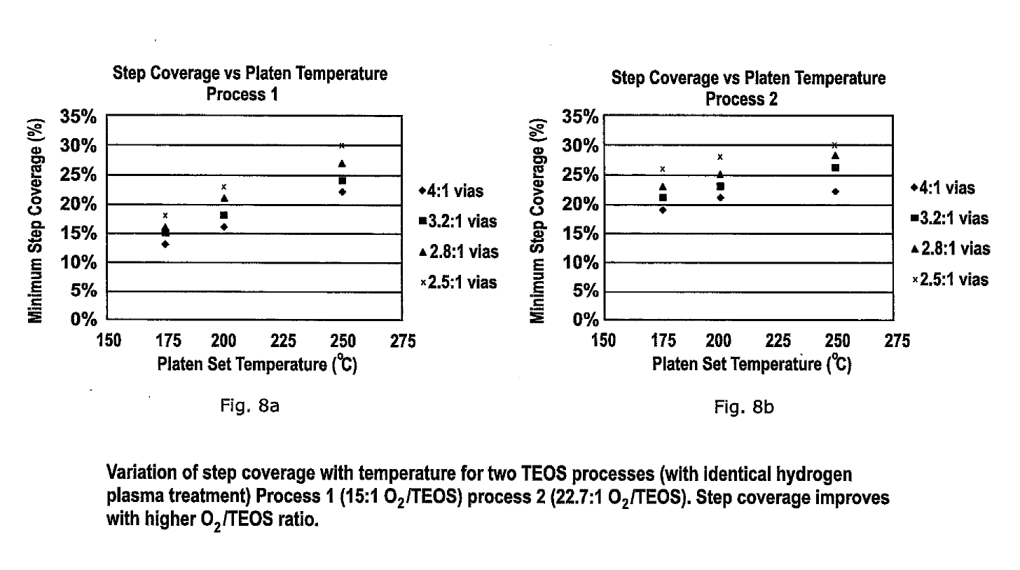

FIGS. 8a and 8b show variation of a step coverage with temperature for two TEOS processes (with identical hydrogen plasma treatment) Process 1 (15:1 O₂/TEOS) and process 2 (22.7:1 O₂/TEOS). Step coverage improves with higher O₂/TEOS ratio;

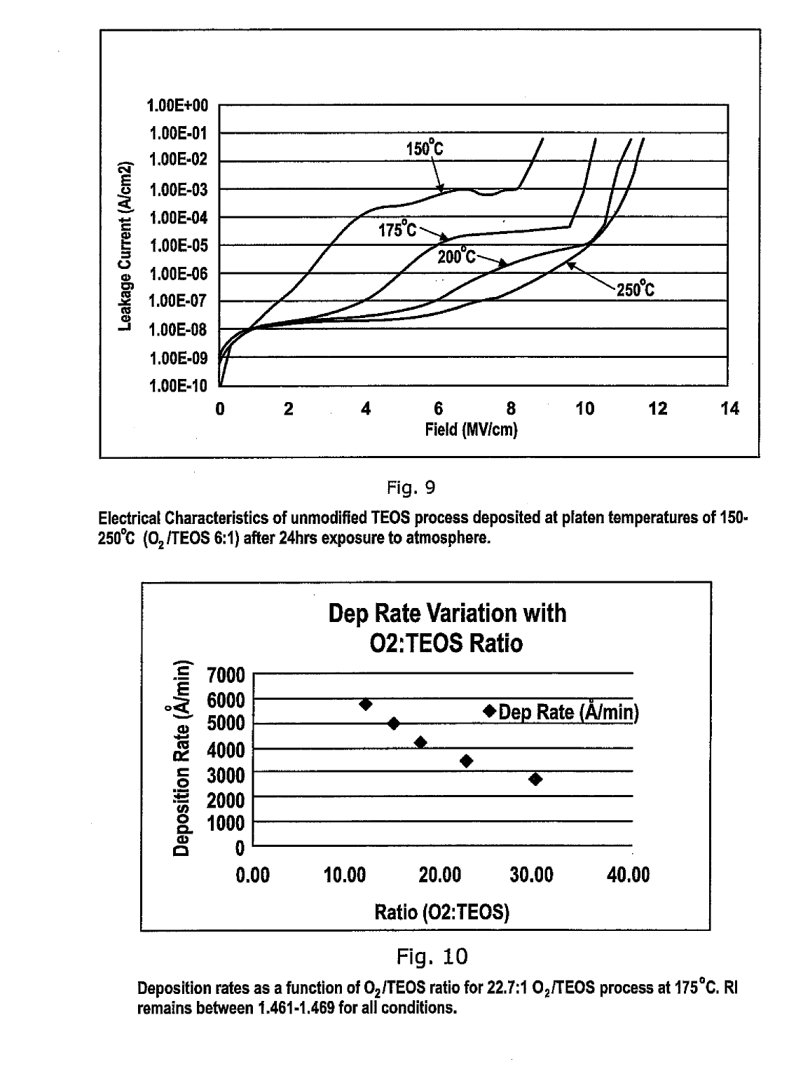

FIG. 9 shows electrical characteristics of unmodified TEOS process deposited at platen temperatures of 150-250° C. (O2/TEOS 6:1) after 24 hrs exposure to atmosphere;

FIG. 10 shows deposition rates as a function of O2/TEOS ration for 22.7:1 O₂/TEOS process at 175° C. The refractive index (RI) remains between 1.461-1.469 for all conditions;

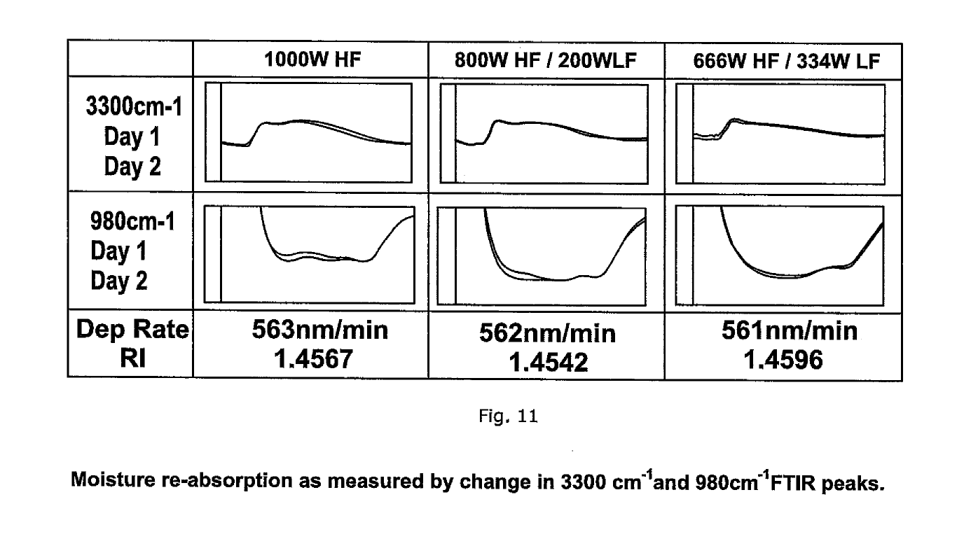

FIG. 11 shows moisture re-absorption as measured by change in 3300 cm⁻¹ and 980 cm⁻¹ FTIR peaks;

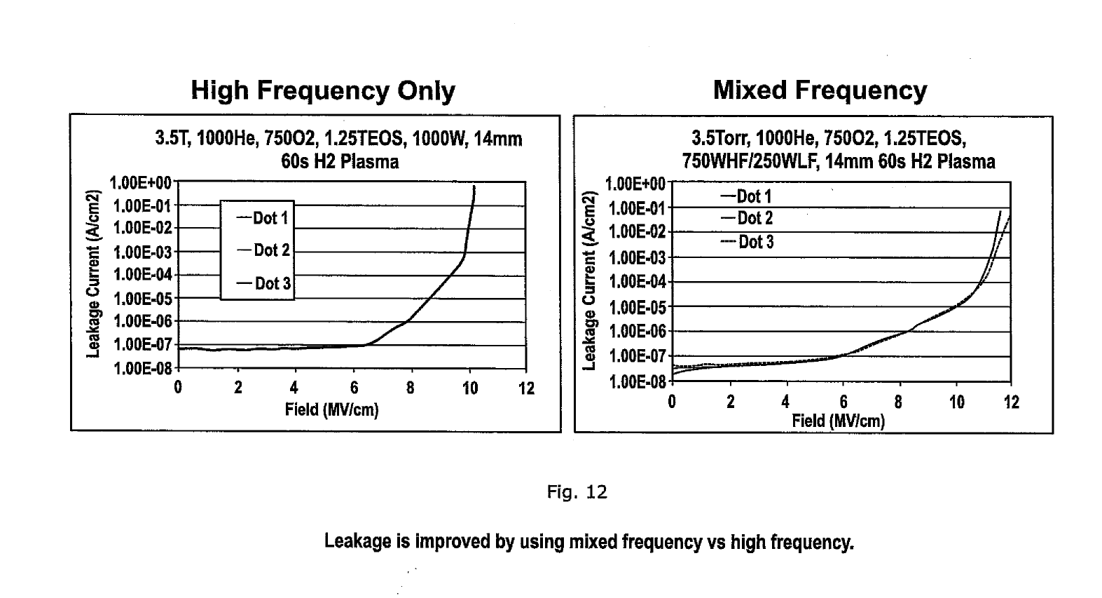

FIG. 12 shows leakage is improved by using mixed frequency vs high frequency;

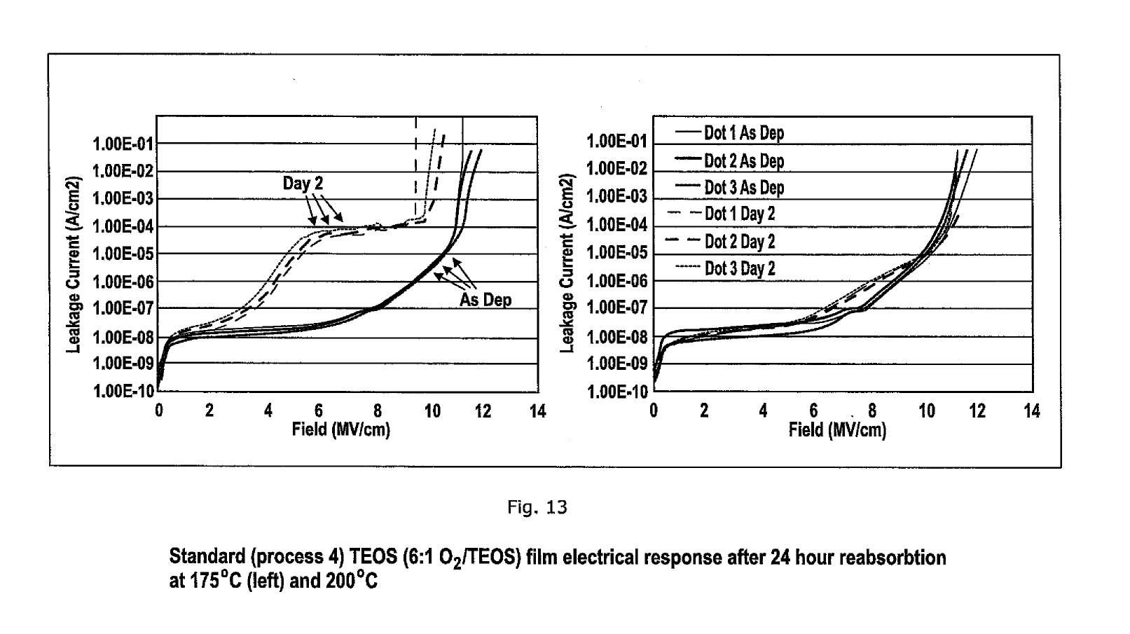

FIG. 13 shows standard (process 4) TEOS (6:1 O₂/TEOS) film electrical response after 24 hour reabsorbtion at 175 (left) and 200° C.;

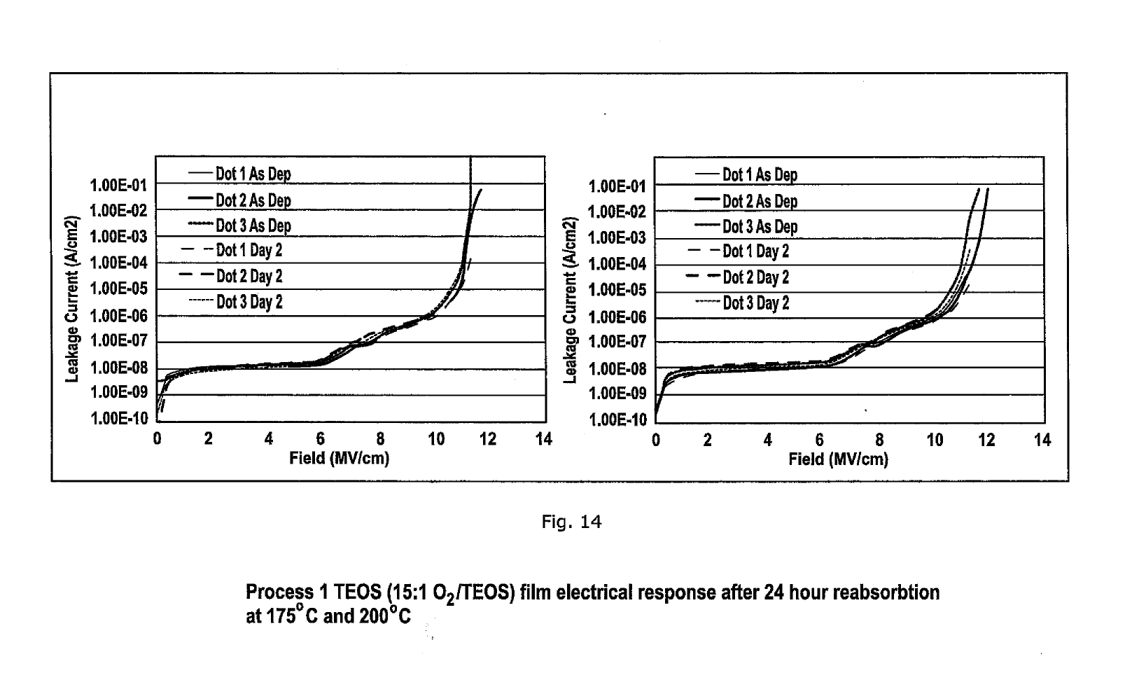

FIG. 14 shows process 1 TEOS (15:1 O₂/TEOS) film electrical response after 24 hour reabsorbtion at 175° C. and 200° C.;

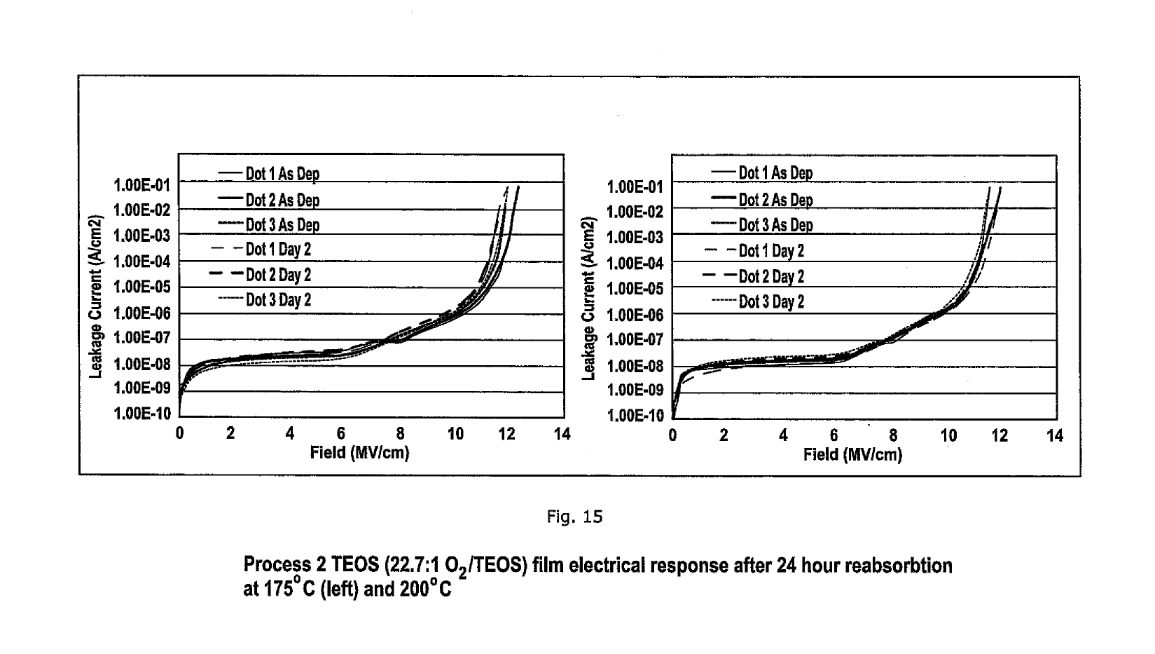

FIG. 15 shows process 2 TEOS (22.7:1 O₂/TEOS) film electrical response after 24 hour reabsorbtion at 175 (left) and 200° C.;

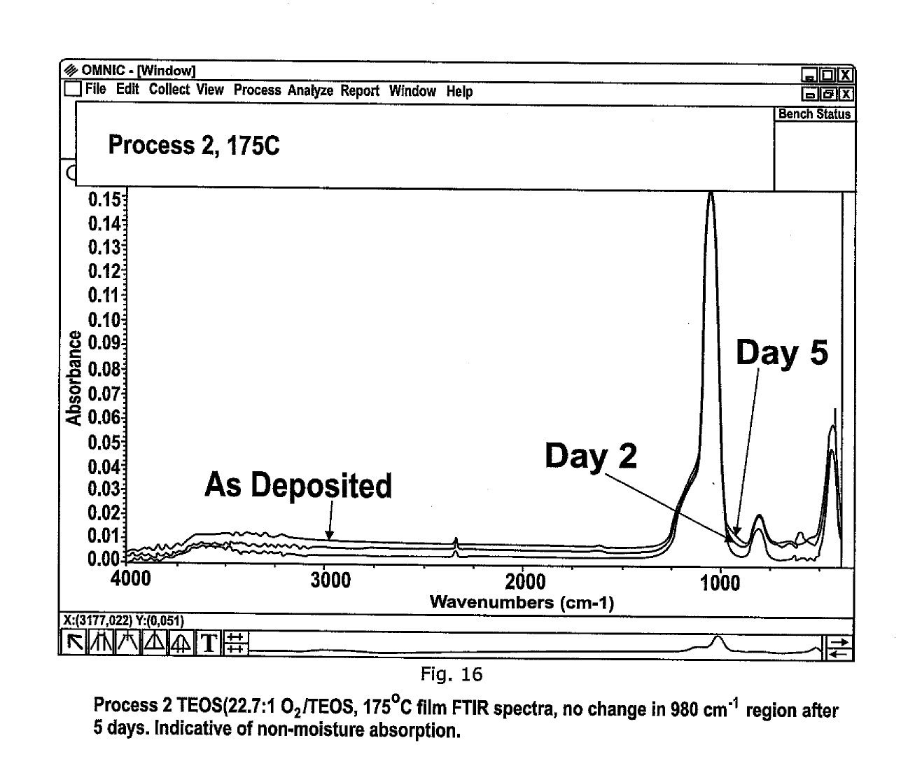

FIG. 16 shows process 2 TEOS (22.7:1 O₂/TEOS, 175° C.) film FTIR spectra, no change in 980 cm⁻¹ region after 5 days. Indicative of no-moisture absorption.

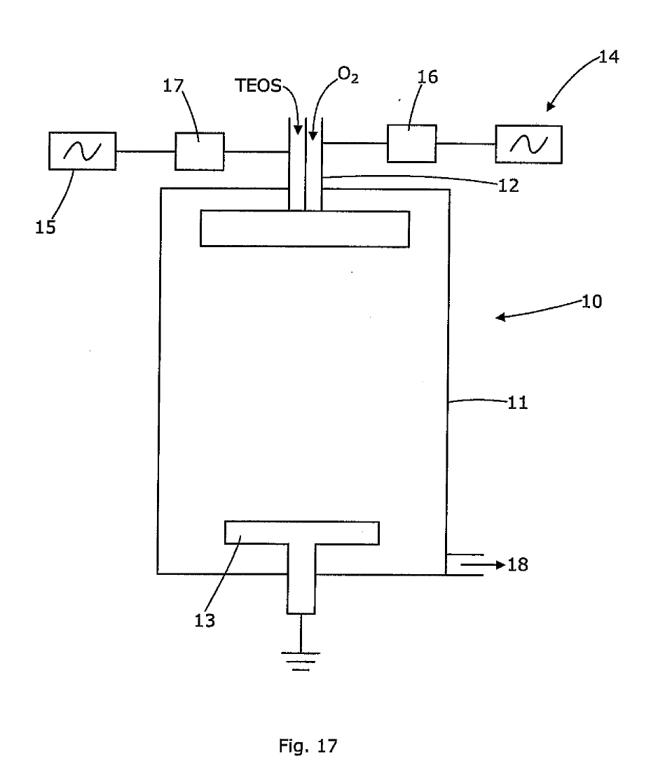

FIG. 17 is a schematic drawing of the apparatus used for deposition.

In FIG. 17 a schematic apparatus for performing the embodiments of the invention is generally illustrated at 10. It comprises a chamber 11, a showerhead 12, a waversupport 13 and respective high and low frequency sources 14 and 15. The showerhead 12 is arranged to receive two precursors (TEOS and O₂). Matching units 16 and 17 are provided for the high and low frequency sources 14 and 15 respectively and a pumped outlet 18 is provided for removing surplus reaction gases.

Using an apparatus a series of experiments were carried out using the following process conditions:

Process 1—DEP: 2400 mT, 1500 sccm O₂, 1000 sccm He, 1.0 ccm TEOS, 666 W HF, 334 W LF, 14 mm ES (15:1)

PLAS: 2000 mT, 1000 sccm H₂, 1000 W HF, 20 mm ES

Process 2—DEP: 2000 mT, 1500 sccm O₂, 1000 sccm He, 0.66 ccm TEOS, 666 W HF, 334 W LF, 14 mm ES (22.7:1)

PLAS: 2000 mT, 1000 sccm H₂, 1000 W HF, 20 mm ES

Process 3—DEP: 2800 mT, 500 sccm O₂, 1000 sccm He, 1.25 ccm TEOS, 900 W HF, 11 mm ES (4:1)

Process 4—DEP: 3500 mT, 750 sccm O₂, 1000 sccm He, 1.25 ccm TEOS, 666 W HF, 334W LF, 14 mm ES (6:1)

PLAS: as described or 2000 mT, 1000 sccm H₂, 1000 W HF, 20 mm ES

Where the process pressure is measured in mT, the O₂, TEOS and He carrier gas flows are in sccm, RF power is measured in watts with HF being 13.56 MHz and LF at 375 kHZ and the electrode (showerhead) to substrate separation ES is in mm

The conditions set out in the above processes are split between an initial deposition process (DEP) and a subsequent plasma treatment (PLAS). The pressure given is the chamber pressure. The helium is used as the process carrier gas. The ratio given in brackets is the ratio off O₂ to TEOS. FIG. 1 shows the effect of H₂ plasma treatment on a low temperature 200° C.) deposited film. Leakage breakdown is generally regarded as occurring somewhere between 1.00 E-07 and 1.00 E-06 and it would be seen that the hydrogen plasma treated film has significantly improved the breakdown of characteristics.

FIG. 2 illustrates at the relationship between no plasma treatment and plasma treatment on films deposited at 150° C. and it is again seen that the breakdown characteristics are improved. FIG. 3 similarly illustrates such characteristics in dependence on when the plasma treatment takes place and it would be seen that it is effective even after quite a lengthy vacuum break but that it seems to be advantageous to have a vacuum break at least up until 24 hours.

FIG. 4 shows the FTIR spectra for a number of films having different lengths of the plasma treatment. When compared with the film having no plasma treatment it would be seen that the plasma treatment removes OH peaks at ˜3300 and 980 CM⁻¹. There is also a very small peak at 2340 CM⁻¹ which indicates the presence of Si—H bonds on more near the surface of the film which would make the film hydrophobic and reduce absorption of water vapour on or through the surface of the film, which has relative little OH in its bulk.

FIGS. 5 and 6 illustrate the effect of different types of anneals and it would be observed that the H₂ plasma treatment is significantly better than preventing reabsorbtion. FIG. 7 looks at the reabsorbtion over time.

Thus from these Figures it can be seen that the H₂ plasma treatment reduces the moisture in the film and reduces the rate of reabsorbtion into the film, probably, at least in part, by creating a hydrophobic surface. The results are excellent even at a deposition temperature of 150° C. It is therefore likely that serviceable films can be obtained below this temperature. The treatment can be carried out after a vacuum break and they possibly be enhanced by such a break.

Preferably the H₂ plasma treatment temperature is low, for example, 200° C. or even lower, around 125° C. or 150° C.

It is also noted that the use of helium and NH₃ plasma treatments and H₂ furnace anneal do not provide the same results.

FIGS. 8a and 8b show the step coverage against the temperature of the support of platen 13. The step coverage improves as temperature is increased and as the O₂/TEOS ratio is increased. However, acceptable step coverage can be achieved at historically low temperatures.

FIG. 9 shows the effect of deposition temperature on the leakage current of a plasma treated film and it will be seen that the results are better at high temperature but with the plasma acceptable results can be achieved at quite low temperatures.

FIG. 10 illustrates the relationship of deposition rate to 0₂/TEOS ratio and it would be seen that the deposition rate falls as the ratio is increased.

As has been explained above the showerhead is preferably powered at mixed frequencies and a typical arrangement is a high frequency of 13.56 MHz and a low frequency of 375 kHz. It is however believed that the low frequency component could be increased in frequency at least up until 2 MHz. It has been determined that the introduction of the low frequency component does not change the deposition rate and therefore is not believed to be increasing the density of the film by ion bombardment. FIG. 11 shows the effect of introducing the low frequency component on reabsorbtion. The deposition conditions for this experiment were as set out in process 4 subject to the variation in the RF components indicated in the figure. There is visibly less reabsorbtion when mixed frequency is used as opposed to a single 13.56 MHz RF source. With no significant changes in deposition rate or refractive index of the SiO2 film it is likely that the LF component is changing the gas species in the plasma. FIG. 12 compares the difference in leakage current between high frequency only and mixed frequency. The references to dot1, dot2, and dot3 indicate measurements at different points on the waver. It will be seen that there is a significant improvement in the leakage characteristics. In general it can be concluded that the presence of the low frequency power provides less OH reabsorbtion and a higher breakdown voltage.

FIGS. 14 to 16 effectively compare the electrical response after 24 hours reabsorbtion at 175° C. and 200° C. for different O₂/TEOS ratios. It would be seen that at the low ratio of 6:1 there is significant reabsorbtion at 175° C. but the extent of the deterioration and performance decreases when the ratio is increased.

FIG. 16 illustrates the good absorbtion performance of a process 2 film. From the above it can be seen that a film deposited at temperatures below 200° C. with good leakage characteristics and good step coverage can be achieved at a relatively high O₂/TEOS ratio such as a round 22:1 utilising mixed frequency RF power and ideally an H₂ plasma treatment step. However the data also shows that improved films can be achieved using a selection of these criteria.

It is envisaged that films may be deposited at temperatures as low as 125° C.

1. A method of depositing an inorganic SiO₂ film at temperatures below 250° C. using plasma enhanced chemical vapour deposition (PECVD) in a chamber including supplying tetraethyl orthosilicate (TEOS) and O₂, as precursors, with an O₂/TEOS ratio of between 15:1 and 25:1.

2. A method as claimed in claim 1 wherein the precursors are deposited using an RF driven showerhead wherein the showerhead is driven using a high frequency component and a low frequency component.

3. A method as claimed in claim 2 wherein the high frequency component is at 13.56 MHz and the low frequency component is 350 kHz-2 MHz.

4. A method as claimed in claim 2 wherein the power supplied at the high frequency is approximately twice the power of the low frequency component.

5. A method as claimed in claim 1 further including performing an H₂ plasma treatment on the as deposited film.

6. A method as claimed in claim 5 wherein the H₂ plasma treatment is performed after a vacuum break.

7. A method as claimed in claim 5 wherein the H₂ plasma treatment forms or reforms Si—H bonds on the surface of the film.

8. A method of PECVD a SiO₂ film using a TEOS precursor and an oxygen containing precursor including performing an H₂ plasma treatment on the as deposited film.

9. A method as claim 8 wherein the precursors are deposited through an RF driven showerhead and wherein the showerhead is driven using a high frequency component and a low frequency component.

10. A method of PECVD of an SiO₂ film at temperatures below 250° C. using TEOS and an oxygen containing precursor deposited through a RF driven showerhead wherein the showerhead is driven using a high frequency component and a low frequency component.

11. A method as claimed in claim 10 wherein the high frequency component is 13-5 MHz and the low frequency component is in the range 350 10 kHz-2 MHz.

12. A method as claimed in claim 10 wherein the film deposited at temperatures in the range about 150° C.-about 200° C.

13. A method as claimed in claim 5 wherein a single RF frequency is used for the H2 plasma.

14. A method as claimed in claim 13 wherein the single RF frequency is 13.56.

15. A method as claimed in claim 5 wherein the plasma temperature is in the range about 125° C. to about 250° C., preferably about 200° C.
